(19) United States
(12) Patent Application Publication
(10) Pub. No.: US 2021/0366791 A1
(43) Pub. Date: Nov. 25, 2021

(54) PLASMA PROCESSING DEVICE AND METHOD FOR PROCESSING SAMPLE USING SAME

(71) Applicant: Hitachi High-Technologies Corporation, Minato-ku, Tokyo (JP)

(72) Inventor: Keiichi TANAKA, Tokyo (JP)

(21) Appl. No.: 16/495,369

(22) PCT Filed: Nov. 27, 2018
(86) PCT No.: PCT/JP2018/043542

§ 371 Date: Sep. 18, 2019

(51) Int. Cl. H01L 21/66; H01L 21/3065; H01J 37/32

(52) U.S. Cl. CPC H01L 22/26; H01L 21/3065; H01J 37/3244; H01J 2237/2007; H01J 2237/3341; H01J 2237/002; H01J 37/32724

(57) ABSTRACT

There is provided a sample processing method including: an adsorption step forming a reactant layer on a sample surface inside a processing chamber in a state where plasma is generated by a plasma generation unit in a plasma generation chamber connected to the processing chamber; a desorption step of desorbing the reactant layer from the surface of the sample by heating the sample with a heating lamp disposed outside the processing chamber and a heater disposed inside the sample stage; a cooling step of cooling the sample heated in the desorption step; and repeating the above steps a plurality of times, wherein in the adsorption step, a control unit performs feed-forward control over the heating lamp and the heater to set the sample to a first temperature state, and in the desorption step, the heater is subjected to feed-back control to set the sample to a second temperature state.

### TECHNICAL FIELD

The present invention relates to a plasma processing device that performs etching processing by plasma irradiation and heating of a sample to be processed, and a method for processing a sample using the same.

### BACKGROUND ART

Due to demands on lower power consumption and increased storage capacity for a semiconductor device, further miniaturization and three-dimension of a device structure have been in progress. In manufacturing a device with a three-dimensional structure, it is required to form a circuit pattern having a higher aspect ratio as an integrated circuit is further miniaturized. Therefore, in addition to “vertical etching” which is performed on a related wafer surface in a direction vertical, “isotropic etching” in which etching can also be performed in a horizontal direction have been frequently used. In the related art, the isotropic etching is performed by wet processing using a chemical solution, but due to the progressed miniaturization, a problem of pattern collapse and processing controllability caused by surface tension of the chemical solution has become obvious along with the process of miniaturization. Therefore, in the isotropic etching, it is necessary to replace the related wet processing using the chemical solution with dry processing not using the chemical solution.

As a method for performing isotropic etching with high accuracy by dry processing, a processing technique for forming a pattern with controllability at an atomic layer level has been developed in PTL 1. A technique called Atomic Level Etching (ALE) has been developed as the processing technique for forming a pattern with controllability at such an atomic layer level, and PTL 1 discloses a technique of performing etching processing on a body to be processed at an atomic layer level by supplying microwaves in a state where an etchant gas is adsorbed on the body to be processed to generate plasma of a low electron temperature of an inert gas such as a rare gas (Ar gas) and separating constituent atoms of a substrate to be processed which are combined with the etchant gas by heat generated by activation of the rare gas from the body to be processed without breaking a bond.

In addition, PTL 2 describes an etching method, including: first adsorbing a radical generated by plasma on a surface of an etched layer on a wafer and forming a reaction layer by a chemical reaction (adsorption step), applying heat energy to the wafer to desorb and remove the reaction layer (desorption step), then cooling the wafer (cooling step), and cyclically repeating the adsorption step, the desorption step, and the cooling step, as an etching method for performing adsorption and desorption with controllability at an atomic layer level.

With this method, in the absorption step, when the reaction layer formed on the surface reaches a certain thickness, the reaction layer prevents the radical from arriving at an interface between the etched layer and the reaction layer, thus rapidly decelerating growth of the reaction layer. Therefore, even when an incidence amount of the radical varies inside a complicated pattern form, there are advantages that an altered layer with a uniform thickness can be formed by adequately setting sufficient absorption time, and the amount of etching can be made uniform without depending on the pattern form.

Moreover, since the amount of etching per cycle can be controlled at a level of several nanometers or below, there is an advantage that adjustment of a processing amount with a dimensional accuracy of several nanometers can be permitted. Further, there is also an advantage that highly selective etching can be performed by utilizing a fact that a radical species necessary for forming the reaction layer on the surface of the etched layer and a radical species that etches a film for obtaining (not reducing) a selectivity ratio are different.

### PRIOR ART LITERATURE

### Patent Literature

PTL 1: WO 2013/168509

PTL 2: JP-A-2017-143186

### SUMMARY OF INVENTION

### Technical Problem

In order to control etching at an atomic layer level, it is necessary to minimize the damage to the surface of the sample caused by plasma and to increase the control accuracy over the amount of etching. As a method corresponding to this, as described in PTL 1 and PTL 2, there is a method in which an etchant gas is chemically adsorbed on a surface of a substrate to be processed, and heat energy is applied thereto to desorb a surface layer of the substrate to be processed.

However, since the method described in PTL 1 is a method in which the surface of the substrate to be processed is heated by a rare gas with a low electron temperature activated by microwaves, there are problems that the heating time of the substrate to be processed cannot be shortened and the throughput of the processing cannot be increased.

On the other hand, in a vacuum processing device described in PTL 2, since a plurality of lamps that emit infrared light are used to heat the surface of the substrate to be processed, a wafer as the substrate to be processed can be heated in a relatively short time by controlling a voltage applied to each of the plurality of lamps. Further, since a relatively high energy charged particle or the like cannot be incident onto the surface of the wafer when the wafer is heated, the etchant gas can be adsorbed to desorb the surface layer without damaging the surface of the wafer.

However, in a case of heating using a lamp, the lamp is disposed around the wafer so as not to hinder a flow of radicals generated in a plasma generation region inside a plasma generation chamber to a wafer surface. Therefore, a distance from the lamp to a central portion on the wafer and a distance from the lamp to a peripheral portion on the wafer are different, and a temperature of the central portion is lower than a temperature of the peripheral portion on the wafer; when the surface layer is to be desorbed on the entire surface of the wafer, the processing time at the central portion on the wafer is a factor that determines the throughput.

As a method of solving this problem, an output of the lamp may be increased to increase a temperature rising rate at the central portion on the wafer, but in this case, the peripheral portion on the wafer may be heated to a temperature higher than necessary, which may damage devices formed on the peripheral portion on the wafer.

The invention solves the problems in the related art described above and provides a plasma processing device and a method for processing a sample using the same, which can increase the throughput of the processing by enabling uniform heating of a wafer.

### Solution to Problem

In order to solve the problems described above, the invention provides a sample processing method for processing a sample, the method including: an adsorption step of forming a reactant layer on a surface of a sample placed on a sample stage inside a processing chamber connected to a plasma generation chamber in a state where plasma is generated by a plasma generation unit in the plasma generation chamber into which a processing gas is introduced; a desorption step of desorbing the reactant layer from the surface of the sample by heating the sample with a heating lamp disposed outside the processing chamber and a heater disposed inside the sample stage to vaporize the reactant layer; a cooling step of cooling the sample heated in the desorption step; and repeating the above steps a plurality of times, wherein in the adsorption step, a control unit performs feed-forward control over the heating lamp and the heater to set the sample to a first temperature state, and in the desorption step, the heater is subjected to feed-back control to set the sample to a second temperature state when the control unit controls the heating lamp and the heater to heat the sample.

Further, in order to solve the problems described above, the invention provides a plasma processing device that includes: a plasma generation chamber; a processing gas supply unit that supplies a processing gas to the inside of the plasma generation chamber; a plasma generation unit that generates plasma inside the plasma generation chamber; a processing chamber that is provided internally with a sample stage on which a sample is placed and is connected to the plasma generation chamber; a plurality of heating lamps that are disposed outside the processing chamber to heat the sample placed on the sample stage; a plurality of heaters that are installed inside the sample stage to heat the sample stage; a plurality of temperature measuring elements that are installed corresponding to the plurality of heaters inside the sample stage to measure a temperature of the sample stage; and a control unit that controls the processing gas supply unit, the plasma generation unit, the plurality of heating lamps, and the plurality of heaters, wherein the control unit has a function of performing feed-forward control over the plurality of heating lamps and the plurality of heaters based on a predetermined relationship among temperatures of the plurality of heating lamps, of the plurality of heaters, and of the surface of the sample placed on the sample stage in a state where the plasma generation unit is controlled to generate plasma inside the plasma generation chamber, and a function of performing feed-forward control over the plurality of heaters based on the temperature of the sample stage measured with the plurality of temperature measuring elements while controlling the plurality of heating lamps to heat the sample in a state where the plasma generation unit is controlled to remove the plasma inside the plasma generation chamber.

### Advantageous Effect

According to the invention, an etching rate can be made uniform on the entire surface of a substrate to be processed, and the throughput of the etching processing can be increased.

### BRIEF DESCRIPTION OF DRAWINGS

FIG. 1 is a block diagram showing a schematic configuration of a plasma processing device according to a first embodiment of the invention.

FIG. 2 is a cross-sectional view of a sample stage showing a configuration of the sample stage of the plasma processing device according to the first embodiment of the invention.

FIG. 3 is a plan view of a wafer showing a state where a temperature measuring element is mounted on the wafer in order to obtain a relationship between a temperature of the wafer and a temperature of the sample stage in the plasma processing device according to the first embodiment of the invention.

FIG. 4 is a block diagram showing a control system or the like of the plasma processing device according to the first embodiment of the invention.

FIG. 5 is a block diagram showing an internal configuration of a control unit of the plasma processing device according to the first embodiment of the invention.

FIG. 6 is a timing chart showing an operation timing of each unit when the wafer is treated by using the plasma processing device according to the first embodiment of the invention.

FIG. 7 is a block diagram showing a control system or the like of a plasma processing device according to a second embodiment of the invention.

### DESCRIPTION OF EMBODIMENTS

The invention relates to an etching method for performing adsorption and desorption with controllability at an atomic layer level, wherein feed-forward control is performed to adjust each of heat quantities from a heater and a lamp to a predetermined value at the beginning of an adsorption step, and in a desorption step, feed-back control is performed on the heat quantities from the lamp based on a difference between a temperature detected by a detector disposed inside a sample stage and a target value, thereby improving the processing throughput.

Hereinafter, embodiments of the invention will be described in detail with reference to the drawings.

### First Embodiment

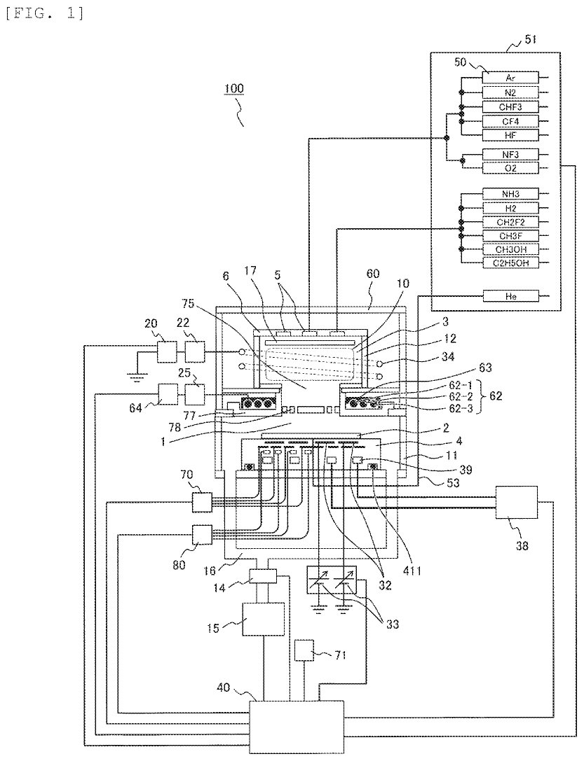

First, an overall configuration of a plasma processing device 100 according to an embodiment of the invention will be described with reference to FIG. 1.

A processing chamber 1 includes a base chamber 11, in which a wafer stage 4 (hereinafter, referred to as stage 4) is installed. The wafer stage 4 is a sample stage on which a wafer 2 as a sample to be processed (hereinafter referred to as wafer 2) is placed. A plasma source that includes a quartz chamber 12, an ICP coil 34 and a high frequency power source is installed above the processing chamber 1, and an Inductively Coupled Plasma (ICP) discharge method is used in the plasma source. The quartz chamber 12 of a cylindrical shape forming an ICP plasma source is installed above the processing chamber 1, and the ICP coil 34 is installed on an outer side of the quartz chamber 12.

The high frequency power source 20 for plasma generation is connected to the ICP coil 34 via a matching device 22. For the frequency of a high frequency power, a frequency band of several tens of MHz, for example, 13.56 MHz is used. A top panel 6 is installed at an upper portion of the quartz chamber 12. A shower plate 5 is installed on the top panel 6, and a gas dispersing plate 17 is installed on a lower portion of the shower plate 5. A processing gas is introduced into the processing chamber 1 from an outer periphery of the gas dispersing plate 17.

A supply flow amount of the processing gas is adjusted by a mass flow controller 50 installed for each gas type. In FIG. 1, NH₃, H₂, CH₂F₂, CH₃F, CH₃OH, O₂, NF₃, Ar, N₂, CHF₃, CF₄, and HF are shown as the processing gas, but other gas may be used.

In order to reduce a pressure of the processing chamber in a lower portion of the processing chamber 1, a vacuum exhaust pipe 16 is connected to an exhaust unit 15. The exhaust unit 15 includes, for example, a turbo molecular pump, a mechanical booster pump, or a dry pump. In addition, in order to adjust the pressure of the processing chamber 1 or a discharge region 3, a pressure adjusting unit 14 is installed on an upstream side of the exhaust unit 15.

An Infrared (IR) lamp unit for heating the wafer 2 is installed between the stage 4 and the quartz chamber 12 forming the ICP plasma source. The IR lamp unit includes an IR lamp 62, a reflection plate 63 that reflects IR light, and an IR light transmission window 77. A circular-shaped lamp is used as the IR lamp 62. Light emitted from the IR lamp 62 is mainly light (referred to herein as IR light) in a visible light region to an infrared light region. In the configuration shown in FIG. 1, IR lamps 62-1, 62-2, 62-3 for three loops are installed as the IR lamp 62, but those for two or four loops may be installed. A reflection plate 63 for reflecting the IR light downward (installation direction of the wafer 2) is installed above the IR lamp 62.

An IR lamp power source 64 is connected to the IR lamp 62. A high frequency cut filter 25 for avoiding a flow of noise of the high frequency power for plasma generation generated at the high frequency power source 20 into the IR lamp power source 64 is installed between the IR lamp power source 64 and the IR lamp 62. Further, the IR lamp power source 64 has a function of permitting powers supplied to the IR lamps 62-1, 62-2, 62-3 to be independently controlled, so that radial distribution of heating amounts of the wafer can be adjusted.

A gas flow path 75 is formed at a center of the IR lamp unit to flow gas supplied from the mass flow controller 50 to the inside of the quartz chamber 12 to a processing chamber 1 side. Then, the gas flow path 75 is provided with a slit plate 78, which has a plurality of open holes for blocking ions and electrons generated in the plasma generated inside the quartz chamber 12 and for transmitting only a neutral gas or a neutral radical therethrough to irradiate the wafer 2 with the same.

In FIG. 1, reference numeral 60 denotes a container that covers the quartz chamber 12, and reference numeral 411 denotes an O-ring for vacuum-sealing between the stage 4 and a bottom surface of the base chamber 11.

A control unit 40 controls ON-OFF of high frequency power supply from the high frequency power source 20 to the ICP coil 34. Further, a type and a flow amount of the gas supplied from each mass flow controller 50 to the inside of the quartz chamber 12 are adjusted by controlling a mass flow controller control unit 51. In this state, the control unit 40 further operates the exhaust unit 15 and controls the pressure adjusting unit 14 to adjust the inside of the processing chamber 1 to a desired pressure (vacuum degree).

Further, in a state where a direct current power source for electrostatic adsorption is operated to electrostatically adsorb the wafer 2 on the stage 4 and the mass flow controller 50 that supplies a He gas between the wafer 2 and the stage 4 is operated, the control unit 40 performs calculation based on temperature distribution information of the wafer 2 measured by the plurality of temperature measuring elements connected to a temperature measuring unit 80, and the control unit 40 controls the IR lamp power source 64, a heater power source 70, and a chiller 38 to make the temperature on the entire surface of the wafer 2 reach a predetermined temperature range.

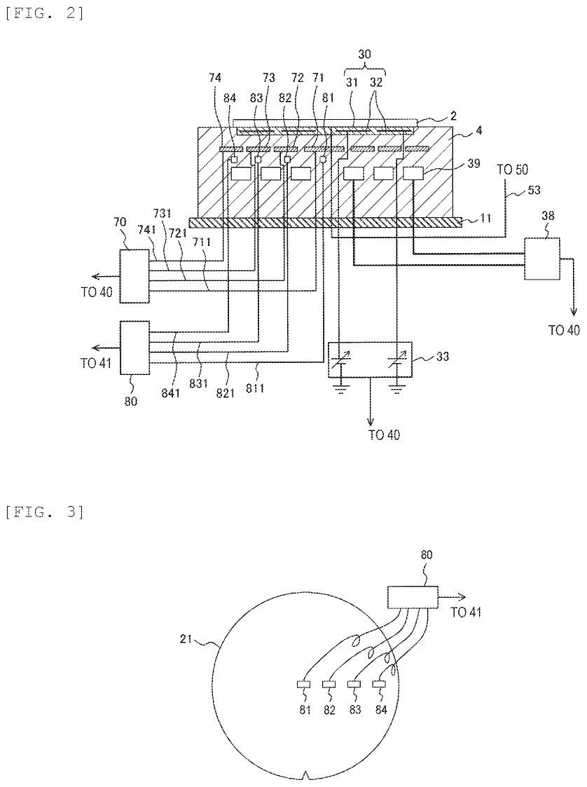

FIG. 2 shows an internal configuration of the stage 4.

An electrostatic adsorption film 31 formed of a dielectric is disposed on an upper surface of the stage 4, and a pair of electrodes 32 are built in the electrostatic adsorption film 31. The pair of electrodes 32 are connected to the direct current power source 33, separately. An electrostatic force is generated on a surface of the electrostatic adsorption film 31 by applying a power to the pair of electrodes 32 with the direct current power source 33, and acts as an electrostatic chuck (hereinafter, the pair of electrodes 32 and the electrostatic adsorption film 31 are collectively referred to as an electrostatic chuck 30). The direct current power source 33 is controlled by the control unit 40.

Further, in order to efficiently cool the wafer 2, a helium gas (He gas) can be supplied between a rear surface of the wafer 2 placed on the stage 4 and the stage 4 via a gas supply pipe 53. The surface of the stage 4 (wafer mounting surface) is coated with a resin such as polyimide to prevent the rear surface of the wafer 2 from being damaged even when heating and cooling are performed while the electrostatic chuck 30 is operated to electrostatically adsorb the wafer 2.

A first heater 71, a second heater 72, a third heater 73, and a fourth heater 74 are disposed on a lower side of the electrostatic adsorption film 31 inside the stage 4. The first heater 71 is connected to the heater power source 70 via a cable 711, the second heater is connected to the heater power source 70 via a cable 721, the third heater 73 is connected to the heater power source 70 via a cable 731, and the fourth heater 74 is connected to the heater power source 70 via a cable 741. The heater power source 70 is controlled by the control unit 40.

On a lower side of each heater, a first temperature measuring element 81 is disposed on a lower portion of the first heater 71, a second temperature measuring element 82 is disposed on a lower portion of the second heater 72, a third temperature measuring element 83 is disposed on a lower portion of the third heater 73, and a fourth temperature measuring element 84 is disposed on a lower portion of the heater 74, respectively corresponding to each heater. The first temperature measuring element 81 is connected to the temperature measuring unit 80 via a cable 811, the second temperature measuring element 82 is connected to the temperature measuring unit 80 via a cable 821, the third temperature measuring element 83 is connected to the temperature measuring unit 80 via a cable 831, and the fourth temperature measuring element 84 is connected to the temperature measuring unit 80 via a cable 841. The temperature measuring unit 80 is connected to the control unit 40.

Further, a refrigerant flow path 39 for cooling the stage 4 by circulating a refrigerant sent out from the chiller 38 inside the stage 4 is formed on a lower side of each temperature measuring element inside the stage 4. The chiller 38 is controlled by the control unit 40.

In an etching process for performing adsorption and desorption on a thin film formed on the surface of the wafer by using the above-described configuration with controllability at an atomic layer level, the wafer 2 is heated to a desired temperature for processing according to the step.

Here, when heating the wafer 2 with the IR lamp 62, the wafer 2 may be heated to obtain a temperature distribution in which an etching rate is uniform over the entire surface of the wafer 2, but in practice, due to a positional relationship between the ring-shaped IR lamp 62 (62-1, 62-2, 62-3) and the wafer 2, when heating the wafer 2 with the IR lamp 62, a portion on the surface of the wafer 2 at a relatively short distance to the IR lamp 62 is likely to be heated, and a temperature difference may occur between this portion and a portion near a central portion on the wafer 2 at a relatively long distance from the IR lamp 62.

Accordingly, it is difficult to perform control to obtain a desired temperature distribution over the entire surface of the wafer 2. This is significant when a relatively large power is applied from the IR lamp power source 64 to the IR lamp 62 in order to increase the temperature rising rate of the wafer 2 by the heating of the IR lamp 62.

In this way, when the temperature on the surface of the wafer 2 does not have a desired temperature distribution, a difference occurs in a formation rate and an etching rate of a reaction layer on the surface of the wafer 2. That is, with respect to the peripheral portion on the wafer 2 having a relatively large amount of incident heat and a high temperature rising rate, the formation rate of the reaction layer near the central portion on the wafer 2 having a relatively small amount of incident heat and a relatively low temperature rising rate is slow, and the etching rate is slow. As a result, there are problems that the processing throughput depends on the processing time near of the central portion on the wafer 2 having a low etching rate, the throughput cannot be increased, and the quality after the etching processing may vary due to unevenness in the etching processing.

In contrast, in the present embodiment, the first to fourth divided heaters 71 to 74 are disposed concentrically inside the stage 4. The first to fourth temperature measuring elements 81 to 84 are mounted under respective heaters. Heating of the stage 4 with the first to fourth heaters 71 to 74 is controlled based on the temperatures detected by the first to fourth temperature measuring elements 81 to 84.

Accordingly, by correcting a deviation from a desired temperature distribution only by heating with the IR lamp 62, the formation rate and the etching rate of the reaction layer can be made uniform over the entire surface of the wafer 2, and the etching processing is homogenized to prevent the variation in quality after the etching processing and to improve the throughput.

Here, the first to fourth temperature measuring elements 81 to 84 detects the temperature inside of the stage 4, not the temperature of the surface of the wafer 2 actually processed. On the other hand, it is difficult to directly measure the temperature of the surface of the wafer 2 being processed. Therefore, a relationship between temperatures of a plurality of positions on the surface of the wafer 2 and temperatures detected by the first to fourth temperature measuring elements 81 to 84 is obtained in advance, and the heating of the stage with the IR lamps 62-1, 62-2, 62-3 for three loops constituting the IR lamp 62 and with the first to fourth heaters 71 to 74 may be controlled so as to obtain a desired temperature distribution on the surface of the wafer 2 based on the temperatures detected by the first to fourth temperature measuring elements 81 to 84.

That is, as the relationship between the temperatures of the plurality of positions on the surface of wafer 2 and the temperatures detected by the first to fourth temperature measuring elements 81 to 84, a relationship between the temperature of the surface of the wafer 2 and the temperatures detected by the temperature measuring elements such as the first to fourth temperature measuring elements 81 to 84 may be provided as a database in order to uniformly heat the wafer 2 over the entire surface with the IR lamps 62-1, 62-2, 62-3, which are the IR lamps 62 for three loops, and with the first to fourth heaters 71 to 74.

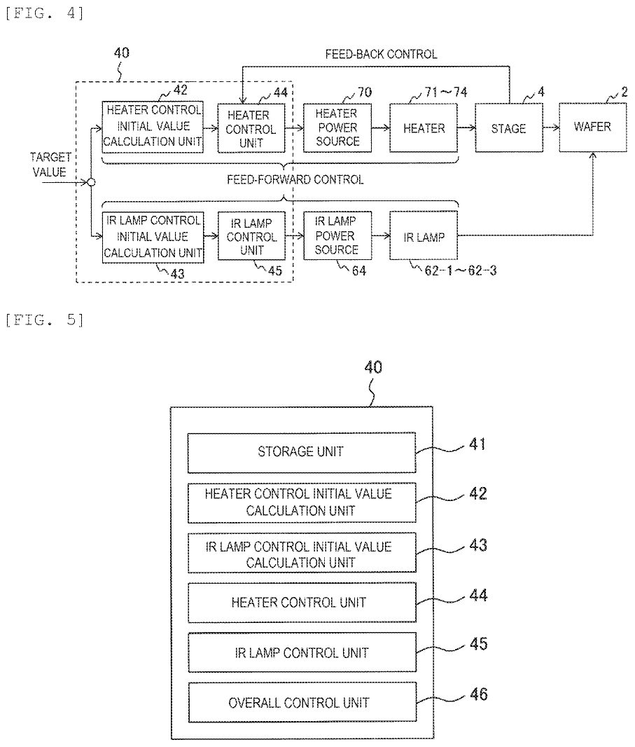

Therefore, in the present embodiment, instead of the wafer 2, a test wafer 21 attached with temperature sensors 91 to 94 (for example, thermocouples) connected to the temperature measuring unit 80 is placed on the stage 4. The temperature sensors 91 to 94 are at a plurality of positions (four positions in an example shown in FIG. 3) on the surface as shown in FIG. 3. A relationship between temperatures detected by the temperature sensors 91 to 94 and the temperatures detected by the first to fourth temperature measuring elements 81 to 84 when a voltage applied to the IR lamps 62-1, 62-2, 62-3 is changed to heat the test wafer 21 is obtained, and the relationship is put into a database.

However, in practice, in order to facilitate a correspondence relationship with the three IR lamps 62-1, 62-2 62-3, a relationship with the temperatures detected by the first to fourth temperature measuring elements 81 to 84, for example, three temperature measuring elements 81, 83 and 84 excluding the second temperature measuring element 82 is put into a database.

In addition, in a state where the test wafer 21 is placed on the stage 4, a relationship between the temperatures detected by the temperature sensors 91 to 94 and the temperatures detected by the first to fourth temperature measuring elements 81 to 84 when a voltage applied to the first to fourth heaters 71 to 74 with the heater power source 70 is changed to heat the test wafer 21 is obtained, and the relationship is put into a database.

Accordingly, the temperature distribution of the wafer 2 can be estimated based on the temperature of the stage 4 detected by the first to fourth temperature measuring elements 81 to 84 when the wafer 2 is heated with the IR lamps 62-1, 62-2, 62-3 and based on the temperature of the stage 4 detected by the first to fourth temperature measuring elements 81 to 84 when the wafers 2 is heated with the first to fourth heaters 71 to 74.

Conversely, voltage application conditions from the IR lamp power source 64 to the IR lamps 62-1, 62-2, 62-3 and voltage application conditions from the heater power source 70 to the first to fourth heaters 71 to 74 can be set to set the temperature distribution of the wafer 2 to a desired temperature distribution based on the database.

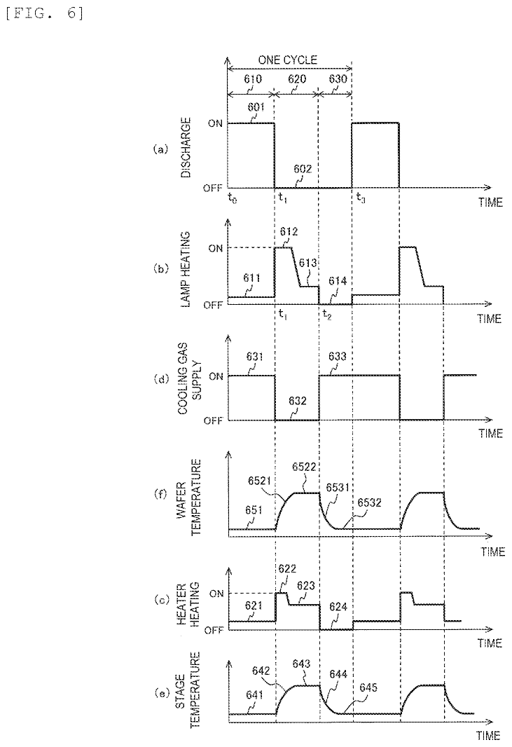

In the present embodiment, as shown in FIG. 4, the heating of the wafer 2 with the IR lamps 62-1, 62-2, 62-3 and the initial heating of the stage 4 by using the first to fourth heaters 71 to 74 are performed by the feed-forward control based on the database stored in a storage unit 41 of the control unit 40 shown in FIG. 5, and the feed-back control is also performed on the first to fourth heaters 71 to 74.

That is, in the feed-forward control, based on an input target value, an IR lamp control initial value calculation unit 43 of the control unit 40 refers to the database stored in the storage unit 41 to calculate the voltage applied to the IR lamps 62-1 to 62-3 under which the temperature of the wafer 2 has a desired distribution.

An IR lamp control unit 45 controls the IR lamp power source 64 based on the voltage applied to the IR lamps 62-1 to 62-3 calculated by the IR lamp control initial value calculation unit 43, and applies the predetermined voltage to the IR lamps 62-1 to 62-3.

Meanwhile, in the feed-forward control, based on the input target value, a heater control initial value calculation unit 42 refers to the database stored in the storage unit 41 to calculate the voltage applied to the first to fourth heaters 71 to 74 under which the temperature of the wafer 2 has a desired distribution.

A heater control unit 44 controls the heater power source 70 based on the initial voltage applied to the first to fourth heaters 71 to 74 calculated by the heater control initial value calculation unit 42, and applies the predetermined voltage as an initial voltage to the first to fourth heaters 71 to 74.

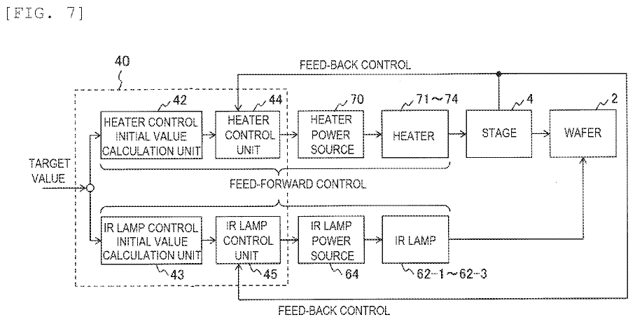

A etching processing of etching the thin film formed on the surface of the wafer 2 at an atomic layer level by using such a configuration will be described with reference to a time chart shown in FIG. 6. The etching processing is divided into an adsorption step 610, a desorption step 620, and a cooling step 630. FIG. 6 shows changes of respective states of (a) discharge, (b) IR lamp heating, (c) heater heating, (d) cooling gas supply, (e) stage temperature, and (f) wafer temperature in the adsorption step 610, the desorption step 620, and the cooling step 630.

First, prior to the adsorption step 610, the wafer 2 is placed on the upper surface of the stage 4 by using a transport unit (not shown), and a voltage is applied between the pair of electrodes 32 with the direct current power source 33 to operate as the electrostatic chuck 30, thereby holding the wafer 2 on the upper surface of the stage 4.

In this state, at a stage where the control unit 40 operates the exhaust unit 15 to exhaust the inside of the processing chamber 1, and the inside of the processing chamber 1 reaches a predetermined pressure (vacuum degree), the mass flow controller control unit 51 is controlled to supply the processing gas from the predetermined mass flow controller 50 to the inside of the quartz chamber 12. By adjusting either or both of the flow amount of the processing gas supplied from the predetermined mass flow controller 50 to the inside of the quartz chamber 12 or the exhaust amount of the pressure adjusting unit 14, the pressure inside the processing chamber 1 is maintained at a preset pressure (vacuum degree).

Here, when a silicon thin film is formed on the surface of the wafer 2, and the silicon thin film is etched, for example, NF₃, NH₃ or CF gas is used as the processing gas supplied from the predetermined mass flow controller 50 to the inside of the quartz chamber 12.

In this way, in a state where the processing gas is introduced to the inside of the processing chamber 1 and the pressure inside the processing chamber 1 is maintained at the preset pressure (vacuum degree), the control unit 40 operates the high frequency power source 20 to apply a high frequency power to the ICP coil 34 to generate plasma inside the quartz chamber 12 surrounded by the ICP coil 34 in the adsorption step 610. (state 601 during (a) discharge ON in FIG. 6).

The gas flow path 75 is formed in the quartz chamber 12 to flow the gas supplied to the inside of the quartz chamber 12 to the processing chamber 1 side. Then, the gas flow path 75 is provided with the slit plate 78, which has a plurality of holes formed for blocking ions and electrons generated in the plasma inside the quartz chamber 12 and for transmitting only a neutral gas or a neutral radical therethrough to irradiate the wafer 2 with the same.

Accordingly, the plasma generated inside the quartz chamber 12 flows to the processing chamber 1 side through the plurality of holes formed in the slit plate 78, but cannot pass through a sheath region formed in a hole wall portion of the slit plate 78 and remains inside the quartz chamber 12.

On the other hand, in a part of the processing gas supplied to the inside of the quartz chamber 12, there is a so-called excitation gas (radical) which is excited by a plasmatized gas but is not plasmatized. Since the excitation gas has no polarity, the excitation gas can pass through the sheath region formed in the hole portion of the slit plate 78, and is supplied to the processing chamber 1 side.

At the processing chamber 1 side, the wafer 2 is adsorbed by the electrostatic chuck 30, and a cooling gas (He) is supplied from the gas supply pipe 53 between the wafer 2 and the surface of the electrostatic chuck 30. (state 631 during (d) ON in FIG. 6).

At this time, a voltage is applied to the IR lamp 62 to set the IR lamp heating in (b) of FIG. 6 to a state 611, a voltage is applied to the first to fourth heaters 71 to 74 to set the heater heating in (c) of FIG. 6 to a state 621, the temperature of the stage 4 is set to a state 641 in (e) of FIG. 6, and the temperature of the wafer 2 is set to a state 651 in (f) of FIG. 6. Here, the temperature of the wafer 2 is set and maintained at a temperature (for example, room temperature ±20° C.) suitable for causing the excitation gas adsorbed on the surface of the wafer 2 to react with the surface layer of the wafer 2 to form a reaction layer, and preventing the reaction from proceeding further.

In order to set the temperature of the wafer 2 to a state 651 in (f) of FIG. 6, the feed-forward control is performed for each of the IR lamps 62-1 to 62-3 and the first to fourth heaters 71 to 74, separately.

In this state, a part of the excitation gas supplied to the processing chamber 1 side is adsorbed on the surface of the wafer 2 held on the upper surface of the stage 4 to form a reaction layer with the surface layer of the wafer 2.

After the excitation gas is continuously supplied to the processing chamber 1 side for a certain period of time (during discharge ON: 601 from time t₀ to time t₁ in FIG. 6) and the reaction layer is formed on the entire surface of the silicon thin film formed on the surface of the wafer 2, the supply of the high frequency power from the high frequency power source 20 to the ICP coil 34 is shut off to stop the generation of plasma inside the quartz chamber 12 (state 602 during (a) discharge OFF in FIG. 6). Accordingly, the supply of the excitation gas from the quartz chamber 12 to the processing chamber 1 is stopped, and the adsorption step 610 is ended.

In this state, the supply of the cooling gas (He) from the gas supply pipe 53 is stopped (state 632 during (d) cooling gas supply OFF in FIG. 6), and the cooling of the wafer 2 is stopped.

Next, the processing enters the desorption step 620, a power for the desorption step is supplied from the IR lamp power source 64 to the IR lamp 62 by the feed-forward control (state 612 during (b) lamp heating ON in FIG. 6), and the lamp 62 is made to emit light. Further, the power for desorption step is supplied from the heater power source 70 to the first to fourth heaters 71 to 74 by the feed-forward control (state 622 during (c) heater heating ON in FIG. 6), and the stage 4 is heated with the first to fourth heaters 71 to 74.

Infrared light is emitted from the IR lamp 62 that emits light, the wafer 2 placed on the stage 4 is heated by the infrared light transmitting through the IR light transmission window 77 of quartz, and further, heat is received from the stage 4 heated with the first to fourth heaters 71 to 74 (642 in (e) stage temperature in FIG. 6), so that the temperature of the wafer 2 rises (6521 in (f) wafer temperature in FIG. 6).

When the state 612 during IR lamp heating ON is continued and the temperature of the wafer 2 reaches a predetermined temperature (for example, 200° C.), the power supplied from the IR lamp power source 64 to the IR lamp 62 is switched by the feed-forward control to obtain a state 613 during IR lamp heating ON.

On the other hand, after a certain period of time has elapsed, the power supplied from the heater power source 70 to the first to fourth heaters 71 to 74 is switched from the state 622 during heater heating ON to a state 623 during heater heating ON. At this time, the first to fourth heaters 71 to 74 are subjected to the feed-back control for correction based on a difference (residual) between the temperature of the stage detected by the first to fourth temperature measuring elements 81 to 84 (state 643 in (e) stage temperature in FIG. 6) and a target temperature of the stage 4, so as to maintain the temperature of the wafer 2 within a predetermined temperature range such as temperature 6522.

In this way, when the wafer 2 heated by the infrared light emitted from the IR lamp 62 and the first to fourth heaters 71 to 74 is maintained within a predetermined temperature range for a certain period of time (state 6522 in (f) wafer temperature in FIG. 6), a reactive substance that forms the reaction layer formed on the surface of the wafer 2 is vaporized and desorbed from the surface of the wafer 2. As a result, an outermost surface layer of the wafer 2 is removed by one layer.

After the wafer 2 is heated for a predetermined time (time from the start of lamp heating ON: 612 at time t₁ to the end of lamp heating ON: 613 at time t2 in (b) of FIG. 6) with the IR lamp 62 and the first to fourth heaters 71 to 74, the power supply from the IR lamp power source 64 to the IR lamp 62 is stopped, the heating with the IR lamp 62 is ended (614 in (b) lamp heating OFF in FIG. 6), the power supply from the heater power source 70 to the first to fourth heaters 71 to 74 is stopped (624 in (c) heater heating OFF in FIG. 6), and the desorption step 620 is ended.

In this state, the supply of the cooling gas (He) between the rear surface of the wafer 2 and the electrostatic chuck 30 is started from the gas supply pipe 53 (state 633 during (d) cooling gas supply ON in FIG. 6: cooling step 630). The supplied cooling gas exchanges heat between the stage 4 and the wafer 2 which are cooled by the refrigerant flowing through the refrigerant flow path 39. At this time, the temperature of the stage 4 cooled by the refrigerant decreases in a relatively short time, and is cooled as shown by curves 644 to 645 in (e) of FIG. 6. Accordingly, the temperature of the wafer 2 is cooled in a relatively short time to a temperature (wafer temperature 6532 in (f) of FIG. 6) suitable for forming the reaction layer, as shown by the curve of wafer temperature 6531 in (f) of FIG. 6, and the cooling step 630 is ended.

Here, when the etching processing of the wafer 2 is not completed (when a thin film to be removed by etching still remains on the surface of the wafer 2), the adsorption step 610, the desorption step 620, and the cooling step 630 are repeatedly performed.

In this way, in the adsorption step 610, the wafer 2 is heated to the temperature suitable for forming the reaction layer on the surface of the wafer 2. Further, in the desorption step 620, during time: 632 in which the wafer 2 is overheated, the temperature required to desorb the reactive substance from the surface of the wafer 2 is maintained without heating the wafer 2 excessively. Therefore, the etching processing can be performed uniformly over the entire surface of the wafer 2, and the quality of the etching processing can be improved.

Further, since the excitation gas adsorbed on the surface of the wafer 2 can be cooled to the temperature suitable for forming the reaction layer in a relatively short time during cooling of the wafer 2, a cooling time: 633 can be shortened as compared with a case where the temperature of the wafer 2 during the heating is not controlled, and the time of one cycle can be shortened to increase the throughput of the processing.

As described above, a cycle starting from generating plasma inside the quartz chamber 12 and adhering the generated excitation gas on the surface of the wafer 2, emitting light from the IR lamp 62 to heat the wafer 2 and to vaporize the reactive substance and desorb the same from the surface of the wafer 2, until cooling the temperature of wafer 2 to the temperature suitable for forming the reaction layer is repeated for a predetermined number of times, so that the thin film layers formed on the surface of the wafer 2 can be removed one by one to a desired number of layers.

In this way, by performing the feed-forward control over the IR lamps 62-1 to 62-3 and the first to fourth heaters 71 to 74, the temperature rising rate of the wafer 2 can be increased, the time for the temperature of the wafer 2 reaching the target temperature can be shortened and the throughput can be increased, compared with a case of heating the wafer 2 only with the IR lamps 62-1, 62-2, 62-3 or a case of heating the wafer 2 only with the first to fourth heaters 71 to 74.

Further, in the present embodiment, the first to fourth heaters 71 to 74 are subjected to the feed-back control for correction based on the difference (residual) between the temperature of each part of the stage 4 detected by the first to fourth temperature measuring elements 81 to 84 and the target temperature of each part of the stage 4 after the start of heating with the IR lamps 62-1, 62-2, 62-3 and the first to fourth heaters 71 to 74.

When the temperature of the wafer 2 is heated to be uniform over the entire surface of the wafer 2, the etching of the peripheral portion on the wafer 2 proceeds earlier than the central portion on the wafer 2, and uniform etching processing is not performed. In order to solve this problem, heating may be performed such that the temperature near the central portion on the wafer 2 is higher than that of the peripheral portion on the wafer 2. By performing the feed-back control over the first to fourth heaters 71 to 74 as described above, each part of the wafer 2 can be set to a desired temperature, the uniformity of the etching processing can be improved and the accuracy of the etching can be improved.

As described above, in the initial stage of the etching processing, the IR lamps 62-1, 62-2, 62-3 and the first to fourth heaters 71 to 74 are subjected to the feed-forward control to heat the wafer 2 to a target temperature in a short time, and after the start of heating of the wafer 2, the first to fourth heaters 71 to 74 are subjected to the feed-back control based on the temperature of the stage 4 detected by the first to fourth temperature measuring elements 81 to 84. Accordingly, the accuracy of the etching processing can be improved, and the throughput can be improved.

### Second Embodiment

In the first embodiment described above, a method has been described in which the IR lamps 62-1, 62-2, 62-3 and the first to fourth heaters 71 to 74 are subjected to the feed-forward control to heat the wafer 2 in the adsorption step 610 of the etching processing, and the first to fourth heaters to 74 are subjected to the feed-back control in the desorption step 620.

In contrast, in the present embodiment, a point in which the IR lamps 62-1, 62-2, 62-3 and the first to fourth heaters 71 to 74 are subjected to the feed-forward control to heat the wafer 2 in the adsorption step 610 of the etching processing is the same as that of the first embodiment, but in the desorption step 620, the IR lamps 62-1, 62-2, 62-3 are also subjected to the feed-back control in addition to the feed-back control over the first to fourth heaters 71 to 74. Other configurations and operations are the same as those described in the first embodiment, and a description thereof will be omitted.

FIG. 7 shows a configuration of a control system in the present embodiment corresponding to a configuration of a control system in the first embodiment described in FIG. 4. In FIG. 7, a point different from the configuration of the control system in the first embodiment described in FIG. 4 is that temperature data of the stage 4 detected by the first to fourth temperature measuring elements 81 to 84 attached to the stage 4 is sent to the IR lamp control unit 45 to perform the feed-back control over the IR lamp.

According to the present embodiment, in the desorption step 620 of the etching processing, in addition to the feed-back control over the first to fourth heaters 71 to 74, the IR lamps 62-1, 62-2, 62-3 are also subjected to the feed-back control. Accordingly, the control over the temperature distribution of the wafer 2 can be performed more finely, and the accuracy of the etching processing can be further improved.

While the invention has been described in detail based on the embodiments, the invention is not limited to the above embodiments, and various modifications can be made without departing from the scope of the invention. For example, the embodiments described above are described in detail for easy understanding of the invention, and the invention is not necessarily limited to those including all the configurations described above. In addition, a part of the configuration of the embodiment may be added, deleted, or replaced with another configuration.

### INDUSTRIAL APPLICABILITY

The invention can be applied to a process of etching a surface of a thin film formed in a wafer shape and removing layers one by one in a process for manufacturing a semiconductor device.

### REFERENCE SIGN LIST

1 processing chamber
2 wafer
4 stage
12 quartz chamber
20 high frequency power source
30 electrostatic chuck
34 ICP coil
39 refrigerant flow path
40 control unit
60 container
62 IR lamp
64 IR lamp power source
70 heater power source
71 to 74 first to fourth heaters
80 temperature measuring unit
81 to 84 first to fourth temperature measuring elements

1. A sample processing method for processing a sample, the method comprising:
an adsorption step of forming a reactant layer on a surface of a sample placed on a sample stage inside a processing chamber connected to a plasma generation chamber in a state where plasma is generated by a plasma generation unit in the plasma generation chamber into which a processing gas is introduced;
a desorption step of desorbing the reactant layer from the surface of the sample by heating the sample with a heating lamp disposed outside the processing chamber and a heater disposed inside the sample stage to vaporize the reactant layer; and
a cooling step of cooling the sample heated in the desorption step; and
repeating the above steps a plurality of times, wherein
in the adsorption step, a control unit performs feed-forward control over the heating lamp and the heater to set the sample to a first temperature state, and
in the desorption step, the heater is subjected to feed-back control to set the sample to a second temperature state when the control unit controls the heating lamp and the heater to heat the sample.

2. The sample processing method according to claim 1, wherein in the adsorption step, based on a predetermined relationship among temperatures of the heating lamp, of the heater, and of the surface of the sample placed on the sample stage, the control unit performs the feed-forward control over the heater and the heating lamp to set the sample to the first temperature state.

3. The sample processing method according to claim 1, wherein in the desorption step, the control unit performs the feed-back control over the heater based on a temperature of the sample stage measured by a temperature measuring element installed inside the sample stage.

4. The sample processing method according to claim 1, wherein in the desorption step, the control unit performs the feed-forward control over the heating lamp and the feed-back control over the heater to set the sample to the second temperature state, so as to generate a desired temperature distribution where a temperature near a center of the sample is higher than a temperature of a periphery on the sample.

5. The sample processing method according to claim 1, wherein in the desorption step, the control unit performs the feed-back control over the heating lamp and the heater to set the sample to the second temperature state, so as to generate a desired temperature distribution where a temperature near a center of the sample is higher than a temperature of a periphery on the sample.

6. The sample processing method according to claim 5, wherein when the adsorption step and the desorption step are repeatedly performed, during changing the desorption step to the adsorption step, a helium gas (He) is supplied between the sample and the sample stage to cool the sample.

7. A plasma processing device comprising:
a plasma generation chamber;
a processing gas supply unit that supplies a processing gas to the inside of the plasma generation chamber;
a plasma generation unit that generates plasma inside the plasma generation chamber;
a processing chamber that is provided internally with a sample stage on which a sample is placed and is connected to the plasma generation chamber;
a plurality of heating lamps that are disposed outside the processing chamber to heat the sample placed on the sample stage;
a plurality of heaters that are installed inside the sample stage to heat the sample stage;
a plurality of temperature measuring elements that are installed corresponding to the plurality of heaters inside the sample stage to measure a temperature of the sample stage; and a control unit that controls the processing gas supply unit, the plasma generation unit, the plurality of heating lamps, and the plurality of heaters, wherein
the control unit has a function of performing feed-forward control over the plurality of heating lamps and the plurality of heaters based on a predetermined relationship among temperatures of the plurality of heating lamps, of the plurality of heaters, and of the surface of the sample placed on the sample stage in a state where the plasma generation unit is controlled to generate plasma inside the plasma generation chamber, and a function of performing feed-back control over the plurality of heaters based on the temperature of the sample stage measured with the plurality of temperature measuring elements while controlling the plurality of heating lamps to heat the sample in a state where the plasma generation unit is controlled to remove the plasma inside the plasma generation chamber.

8. The plasma processing device according to claim 7, wherein the sample stage includes an electrostatic chuck that electrostatically adsorbs the sample, and a gas supply unit that supplies a helium gas between the sample placed on the sample stage and the electrostatic chuck, and a flow path along which a refrigerant for cooling the sample stage flows is formed inside the sample stage.

9. The plasma processing device according to claim 7, wherein the control unit has a function of setting the sample to a first temperature by performing the feed-forward control over the plurality of heating lamps and the plurality of heaters based on the predetermined relationship among the temperatures of the plurality of heating lamps, of the plurality of heaters, and of the surface of the sample placed on the sample stage in a state where the plasma generation unit is controlled to generate plasma inside the plasma generation chamber, and a function of setting the sample to a second temperature higher than the first temperature by performing the feed-back control over the plurality of heaters based on a temperature distribution of the sample stage measured by the plurality of temperature measuring elements while controlling the plurality of heating lamps to heat the sample in a state where the plasma generation unit is controlled to remove the plasma inside the plasma generation chamber.

10. The plasma processing device according to claim 7, wherein the control unit has a function of performing the feed-back control over the plurality of heating lamps and the plurality of heaters based on the temperature of the sample stage measured by the plurality of temperature measuring elements when controlling the plurality of heating lamps to heat the sample in a state where the plasma generation unit is controlled to remove the plasma inside the plasma generation chamber.
